(19) United States
(12) Patent Application Publication
(10) Pub. No.: US 2025/0218826 A1
(43) Pub. Date: Jul. 3, 2025

(54) ELECTRONIC DEVICE AND METHOD OF OPERATION THEREOF

(71) Applicant: Samsung Electronics Co., Ltd., Suwon-si (KR)

(72) Inventors: Jonghyun Kim, Suwon-si (KR); Hyeonjun Yun, Suwon-si (KR); Byungyong Choi, Suwon-si (KR); Jongik Hong, Suwon-si (KR); Seungwoo Cha, Suwon-si (KR)

(21) Appl. No.: 18/796,595

(22) Filed: Aug. 7, 2024

(30) Foreign Application Priority Data
Dec. 29, 2023 (KR) 10-2023-0196958

(51) Int. Cl. H01L 21/67

(52) U.S. Cl. CPC H01L 21/67253; H01L 21/67276; H01L 21/67288; H01L 21/67063

(57) ABSTRACT

An electronic device and a method of operating the same are provided. The electronic device includes a communication circuit, at least one processor, and a memory, wherein the memory stores instructions that, when executed by the at least one processor, cause the electronic device to obtain real-time facility data while a target process for a semiconductor wafer is in progress, post-process the real-time facility data, generate at least one factor that quantifies a process state for each time section of the target process based on the processed real-time facility data, and predict a defect index of the target process based on the at least one factor.

### CROSS-REFERENCE TO RELATED APPLICATION

This application claims priority to and the benefit of, under 35 U.S.C. § 119, Korean Patent Application No. 10-2023-0196958 filed at the Korean Intellectual Property Office on Dec. 29, 2023, the entire contents of which are incorporated herein by reference.

### BACKGROUND

This disclosure relates generally to an electronic device and a method of operation thereof.

As the integration of semiconductor devices increases, processes with high difficulty, such as a process for forming a high-aspect ratio contact (HARC) are increasing. Additionally, as process difficulty increases, process defects are increasing.

For example, in the case of the HARC process, a process defect in which the profile of a hole is deformed may occur due to an increase in the number of stacked layers. In order to determine defects in the profile of a hole, it may be necessary to perform a destructive test or conduct an electrical property evaluation on a fab-out wafer or chip after the entire process is completed.

### SUMMARY

Embodiments of the present disclosure are intended to provide an electronic device and a method of operating the same that can predict process defects with high reliability for the entire quantity immediately after the target process without destroying the product.

An electronic device according to an embodiment includes a communication circuit, at least one processor, and a memory, wherein the memory stores instructions that, when executed by the at least one processor, cause the electronic device to obtain real-time facility data while a target process for a semiconductor wafer is in progress, post-process the real-time facility data, generate at least one factor that quantifies a process state for each time section of the target process based on the processed real-time facility data, and predict a defect index of the target process based on the at least one factor.

An electronic device according to an embodiment includes a communication circuit, at least one processor, and a memory, wherein the memory stores instructions that, when executed by the at least one processor, cause the electronic device to obtain real-time facility data while a target process for forming at least one structure on a semiconductor wafer is in progress, post-process the real-time facility data, divide the processed real-time facility data into a plurality of time sections, generate at least one factor based on facility data for each time section or facility data for at least two time sections, and predict a defect index of the target process based on the at least one factor.

A method of operating an electronic device according to an embodiment includes obtaining real-time facility data while a target process for a semiconductor wafer is in progress, post-processing the real-time facility data, generating at least one factor that quantifies a process state for each time section of the target process based on the processed real-time facility data, and predicting a defect index of the target process based on the at least one factor.

According to embodiments, immediately after a target process that is difficult to monitor during the semiconductor manufacturing process, process defects can be predicted with high reliability for the entire quantity without destroying the product.

According to the embodiments, it is possible to diagnose the cause of defects and derive improvement plans immediately after the target process, shorten the product development period, and shorten the verification period of a new facility when expanding facility.

According to embodiments, the process flow of wafers in a semiconductor manufacturing process can be efficiently managed.

### BRIEF DESCRIPTION OF THE DRAWINGS

Embodiments of the present inventive concept will be more clearly understood from the following detailed description taken in conjunction with the accompanying drawings, wherein like reference numerals (when used) indicate corresponding elements throughout the several views, and in which:

FIG. 1 is a schematic plan view and a cross-sectional view showing an example semiconductor device;

FIG. 2 is a block diagram of an example electronic device according to one embodiment;

FIG. 3 is a block diagram of an example program module executed by an electronic device according to an embodiment;

FIG. 4 is a flowchart showing an example method of operating an electronic device according to an embodiment;

FIG. 5 is a diagram conceptually illustrating a method in which an electronic device according to an embodiment generates at least one factor based on facility data for each time section;

FIG. 6 is a diagram illustrating an example method by which an electronic device according to an embodiment obtains a profile of a hole based on at least one factor;

FIG. 7 is a diagram illustrating an example method for an electronic device according to an embodiment to predict a defect index based on at least one factor;

FIG. 8 is a flowchart showing an example method of operating an electronic device according to an embodiment;

FIG. 9 is a diagram illustrating a method for an electronic device according to an embodiment to predict a defect index using a process defect prediction model;

FIG. 10 is a flowchart showing an example method of operating an electronic device according to an embodiment; and

FIG. 11 is a diagram illustrating an example of a computer device implementing an electronic device according to an embodiment.

### DETAILED DESCRIPTION

Hereinafter, with reference to the attached drawings, various embodiments will be described in detail so that those skilled in the art can easily implement the present invention. The invention may be implemented in many different forms and is not limited to the embodiments described herein.

In order to clearly explain the present invention, parts that are not relevant to the description are omitted, and identical or similar components are assigned the same reference numerals throughout the specification.

In addition, the size and thickness of each component shown in the drawings are shown arbitrarily for convenience of explanation, so the present invention is not necessarily limited to that which is shown. In the drawing, the thickness is enlarged to clearly express various layers and regions. And in the drawings, for convenience of explanation, the thicknesses of some layers and regions are exaggerated.

Additionally, when a part of a layer, membrane, region, or plate is said to be “above” or “on” another part, this includes not only cases where it is “directly on” another part, but also cases where there is another part in between. In contrast, when an element is referred to as being “directly on” another element, there are no intervening elements present. In addition, being “above” or “on” a reference part means being located above or below the reference part, and does not necessarily mean being located “above” or “on” it in the direction opposite to gravity.

In addition, throughout the specification, when a part is said to “include” a certain element, this means that it may further include other elements, rather than excluding other elements, unless specifically stated to the contrary.

In addition, throughout the specification, when reference is made to “on a plane,” this means when the target portion is viewed from above, and when reference is made to “in cross-section,” this means when a cross-section of the target portion is cut vertically and viewed from the side.

Also, terms such as “part”, “device”, or “module” listed in the specification can perform at least one function or action, and can be implemented as hardware or software, or as a combination of hardware and software. In addition, a plurality of “parts”, a plurality of “units”, or a plurality of “modules” can be integrated into at least one module and can be implemented with at least one processor except for “part”, “unit”, or “module” that need to be implemented with specific hardware.

In this specification, “transmission” or “provision” may include not only directly transmitting or providing, but also indirectly transmitting or providing through another device or using an alternate path or channel.

In this specification, expressions described as singular may be interpreted as singular or plural, unless explicit expressions such as “one” or “single” are used.

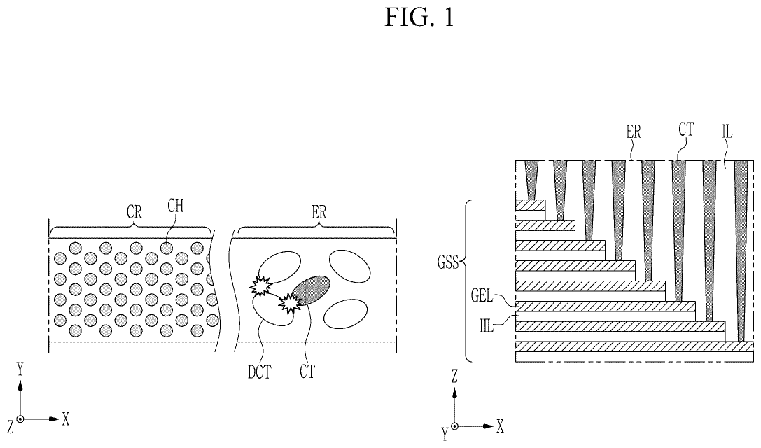

Hereinafter, with reference to FIG. 1, a problem to be solved by an electronic device according to an embodiment will be described.

FIG. 1 is a schematic plan view and a cross-sectional view showing an example semiconductor device. The semiconductor device may be a non-volatile memory device—for example, a NAND flash memory device. An example semiconductor device may include a cell region in which a memory cell structure is provided and a circuit region in which a peripheral circuit structure that controls the operation of the memory cell structure is provided. FIG. 1 is a diagram showing the cell region of an example semiconductor device.

Referring to FIG. 1, the cell region of an example semiconductor device may include a cell array region CR and an extension region ER disposed around the cell array region CR. In the cell array region CR, a gate stacked structure GSS and a channel structure CH may be located on a substrate containing a semiconductor material. Here, the substrate may mean a wafer.

The gate stacked structure GSS may include interlayer insulating layers IIL and gate electrode layers GEL alternately stacked on a substrate in a vertical (i.e., Z-axis) direction, perpendicular to an upper surface of the substrate. Gate electrode layers GEL may provide gate electrodes of a ground select transistor, a plurality of memory cell transistors, and a string select transistor. The gate electrode layer GEL may extend to form a word line.

The channel structure CH may extend in a direction perpendicular to the substrate (Z-axis direction in FIG. 1) through the gate stacked structure GSS. Each channel structure CH forms one memory cell string, and a plurality of channel structures CH may be arranged to be spaced apart from each other in rows and columns on a plane. For example, a plurality of channel structures CH may be arranged in various shapes, such as a grid shape or a zigzag shape, on a plane. The channel structure CH may have a pillar shape.

A portion of the gate stacked structure GSS and a structure for connecting the gate stacked structure GSS to a circuit region or an external circuit may be located in the extension region ER. A plurality of gate electrode layers GEL may extend in one direction (X-axis direction in FIG. 1) and be located in the extension region ER. The extension length of the plurality of gate electrode layers GEL in the extension region ER may become shorter as the distance from the substrate increases. A portion of the gate stacked structure GSS located in the extension region ER may have a stepped structure. Each of the plurality of gate electrode layers GEL in the extension region ER may correspond to one step of a staircase.

In the extension region ER, an insulating layer IL may be located on the gate stacked structure GSS. Contact structures CT each connected to the gate electrode layers GEL and dummy contact structures DCT connected to the substrate through the gate stacked structure GSS may be located in the extension region ER. According to the above description, the portion of the gate stacked structure GSS located in the extension region ER may include a plurality of step surfaces. The contact structure CT may be disposed on one surface of the gate electrode layer GEL forming each step surface. The dummy contact structure DCT may be disposed to penetrate (i.e., extend into) at least one gate electrode layer GEL including the gate electrode layer GEL forming a step surface. At least a portion of the contact structures CT and the dummy contact structures DCT may be surrounded by the insulating layer IL. The term “surrounded” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles.

On a plane (i.e., horizontally, parallel to the upper surface of the substrate), adjacent dummy contact structures DCT may be located approximately at the vertices of a square, and the contact structure CT may be located approximately at the center of the square. In cross-section, the contact structure CT may have an inclined side surface so that the width becomes narrower as it approaches the substrate, depending on the aspect ratio. The contact structure CT may electrically connect the gate electrode layer GEL to the circuit region or external circuit. The dummy contact structure DCT has the same or a similar structure and shape as the contact structure CT, but has no actual function in the semiconductor device and may exist only as a pattern. Electrical signals are not applied to the dummy contact structure DCT, or even if electrical signals are applied, they do not perform the same electrical function as the contact structure CT.

As the number of word lines stacked in a semiconductor device increases, defects in a profile of a hole may occur in the process of etching the hole with a high aspect ratio. For example, as the profile of the hole corresponding to the contact structure CT and the dummy contact structure DCT is deformed during the manufacturing process differently from what was designed, adjacent dummy contact structures DCT contact each other and act as if the word line is electrically disconnected. A word line disconnection defect may occur, or a contact defect may occur due to contact between an adjacent dummy contact structure DCT and a contact structure CT. These defects may occur, for example, in the hole etching process when the critical dimension of the hole is unintentionally increased due to excessive etching.

Meanwhile, unlike the holes corresponding to the channel structure CH, there is a lack of technology for identifying the profile and profile defects of the holes corresponding to the contact structure CT and the dummy contact structure DCT. Specifically, there is no non-destructive measurement technology for holes corresponding to the contact structure CT and the dummy contact structure DCT, or in the case of destructive measurement technology, the number of samples is insufficient, resulting in low consistency. In addition, profile defects of the holes can be accurately detected through electrical property evaluation performed after completion of the entire process (fab-out) rather than immediately after the relevant process, making it difficult to develop and ramp up the product in a timely manner.

Accordingly, the electronic device according to the embodiment disclosed in this specification may generate a factor that can indicate the characteristics of the structure formed by the target process (e.g., profile of the hole) using real-time facility data of the facility performing the target process, and may predict defects in the target process based on the generated factor. According to an embodiment of the inventive concept, defects in the target process can be reliably predicted for the entire quantity immediately after the target process. Additionally, according to an embodiment, the subsequent process flow can be efficiently controlled based on a predicted defect level for each wafer. In addition, according to an embodiment, factors causing defects in the target process can be identified immediately after the target process, thereby shortening the time for improving the process and the facility, and providing specific feedback on the direction of improvement.

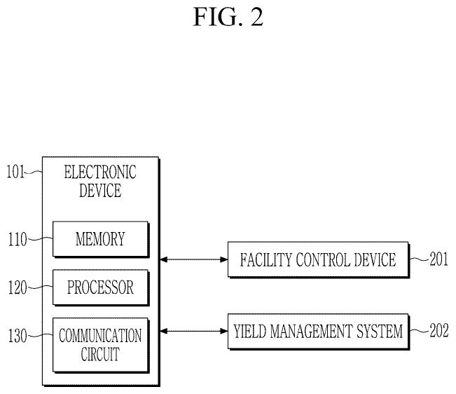

Below, with reference to FIG. 2, an electronic device according to an embodiment will be described.

FIG. 2 is a block diagram of an example electronic device, according to one embodiment of the inventive concept.

Referring to FIG. 2, the electronic device 101 according to one embodiment may include a memory 110, at least one processor 120, and a communication circuit 130.

The memory 110 may store data used by at least one component (e.g., the processor 120 or the communication circuit 130) of the electronic device 101. The memory 110 may store instructions executed by the at least one processor 120. The memory 110 can store data transmitted and received through the communication circuit 130.

At least one processor 120 may be operatively connected to the memory 110 and the communication circuit 130. The processor 120 may control the operation of the electronic device 101 by controlling at least one other component of the electronic device 101 connected to the processor 120.

The processor 120 may execute instructions stored in the memory 110. The processor 120 may execute instructions stored in the memory 110 to cause the electronic device 101 to perform operations described later. The operations described below as being performed by the processor 120 may be performed by the processor 120 and/or at least one other component of the electronic device 101 connected to the processor 120, so it may be understood as being performed by the electronic device 101. As used herein, the term “and/or” includes any and all combinations of one or more of the associated listed items.

The processor 120 may obtain real-time facility data while a target process for a semiconductor wafer is in progress. Real-time facility data may include values measured in real time by sensors in the facility performing the target process. Real-time facility data may include, for example, optical emission spectroscopy (OES) data and fault-detection and classification (FDC) data.

OES data represents the wavelength of light emitted from plasma in a process using plasma and the change in intensity of the light over time. OES data can be used to estimate the elements and amounts of elements present in plasma. For example, the processor 120 may obtain information about the amount of etching by-products based on OES data in an etching process using plasma.

FDC data represents changes in the intensity of signals detected by various sensors in the facility over time. Using FDC data, various parameters of the facility corresponding to each sensor and detect facility abnormalities can be monitored. For example, the processor 120 may obtain information about real-time changes in facility parameters such as temperature, pressure, and power based on FDC data.

According to the above, real-time facility data may include, but is not limited to, measurement values according to (i.e., as a function of) time and/or measurement values according to wavelength. In some embodiments, real-time facility data may include measurements based on location, and/or measurements based on frequency. Real-time facility data can include a variety of continuous measurements.

In one embodiment, the target process may include a process of etching a hole with depth in a semiconductor wafer. Here, the hole with depth may mean a hole with a high aspect ratio. For example, the target process may be a process of etching a hole corresponding to a contact structure (CT in FIG. 1) and a dummy contact structure (DCT in FIG. 1) in the extension region (ER in FIG. 1) among processes of manufacturing a NAND flash memory device including vertically stacked memory cells.

However, the target process is not limited to the above-described embodiment. In some embodiments, it may be applied equally or similarly to a process using plasma during the manufacturing process of a semiconductor device or a process in which facility data that changes in real time can be obtained. The target process may include at least one of an etching process, a deposition process, or an annealing process. The etching process may include, for example, a plasma etching process or a wet etching process. The deposition process may include, for example, a chemical vapor deposition process. Hereinafter, the description will focus on an embodiment in which the target process includes a process of etching a hole.

In one embodiment, the target process may include a plurality of processes. The plurality of processes may include sub-processes included in the process of forming one structure, or may include processes of forming each of the plurality of structures. For example, the plurality of processes may include sub-processes included in the process of forming a hole corresponding to the contact structure (e.g., CT in FIG. 1). Sub-processes may include the same or different types of processes. As another example, the plurality of processes may include a process of forming a hole corresponding to a contact structure (e.g., CT in FIG. 1) and a process of forming a hole corresponding to a dummy contact structure (e.g., DCT in FIG. 1).

The processor 120 may receive real-time facility data through the communication circuit 130 and store such data in the memory 110. For example, the processor 120 may directly receive real-time facility data from the facility or at least one sensor of the facility through the communication circuit 130. As another example, the processor 120 may receive real-time facility data stored in an external server provided separately from the facility through the communication circuit 130.

The processor 120, in one or more embodiments, may be configured to post-process real-time facility data. Post-processing may include, for example, facility noise correction, standardization, normalization, and/or smoothing. Real-time facility data may include, for example, measurements of signal intensity over time. Hereinafter, the value measuring the intensity of the signal over time may be referred to as the first measurement value. Real-time facility data including the first measurement value may be, for example, FDC data or OES data. Real-time facility data may include a first measurement indicating signal intensity over time and a second measurement indicating signal intensity over wavelength. Real-time facility data including the first measurement value and the second measurement value may be, for example, OES data.

The processor 120 may standardize the first measurement value by dividing a value that changes during the target process by a value that is constant during the target process. For example, if the real-time facility data is OES data, the processor 120 may standardize the first measurement value of the etch by-product by dividing it by the first measurement value of the inert gas.

The processor 120 may smooth the first measurement value. For example, the processor 120 may smooth the first measurement value using a moving average. For example, the processor 120 may be configured to calculate the moving average using Equation 1 below. In Equation 1, x is a time in seconds, y(x) on the right side may be the first measurement value at time x, and y(x) on the left side may be the smoothed first measurement value at time x.

$$y ( x ) = \frac{\{ y ( x - 10 ) + y ( x - 9 ) + ⋯ + y ( x + 9 ) \}}{20} \qquad [ Equation 1 ]$$

Equation 1 described above is an equation for the case where the range of the moving average is 20, but it is not limited to this, and the range of the moving average can be changed in various ways.

The processor 120 may smooth the normalized first measurement value. The processor 120 may first perform normalization on the first measurement value and then perform smoothing.

The processor 120 may normalize the second measurement value by dividing an average signal intensity in the first wavelength range by an average signal intensity in the second wavelength range. The second wavelength range includes the first wavelength range, and may be a wider wavelength range than the first wavelength range. This normalization may be referred to as “self wavelength correction” or “self normalization”.

For example, when the real-time facility data is OES data, the real-time facility data may include both the first measurement value and the second measurement value. After performing normalization on the second measurement value, the processor 120 may perform normalization and smoothing on the first measurement value described above.

For example, when the real-time facility data is FDC data, the real-time facility data may include the first measurement value and may not include the second measurement value. The processor 120 may perform normalization and smoothing on the first measurement value.

The processor 120 may generate at least one factor that quantifies a process state for each time section of the target process based on the processed real-time facility data. The processor 120 may divide the processed real-time facility data into a plurality of time sections. For example, the processor 120 may determine that a plurality of time sections have the same time interval, but is not limited to this. As another example, the processor 120 may determine the time section for each time section based on process information of the target process.

For example, because the facility etches a hole from top to bottom, the lower portion of the hole may be deeper than the upper portion of the hole. According to one embodiment, the plurality of time sections of the target process may each correspond to a plurality of depth sections of the hole in which the profile of the hole is divided into a plurality of sections according to the depth.

If the first time section of the first time section and the second time section is ahead of the second time section, the first depth section of the hole corresponding to the first time section may be shallower than the second depth section of the hole corresponding to the second time section. As described above, when the hole is etched from top to bottom, the portion of the hole corresponding to the first depth section may be located above the portion of the hole corresponding to the second depth section.

In one embodiment, facility data for each time section may correspond to a profile for each depth section of the hole. For example, OES data for each time section may indicate the amount of etching by-products generated for each depth section of the hole—that is, the amount of etching. The critical dimension (CD) (or diameter) of the hole may be proportional to the amount of etching. For example, as the etching amount increases, the critical dimension of the hole may increase, and as the etching amount decreases, the critical dimension of the hole may decrease. The change in critical dimension depending on the depth of the hole may correspond to the profile (i.e., contour) of the hole. Therefore, OES data for each time section can correspond to the profile for each depth section of the hole. Although OES data was used as an example, it is not limited to this, and changes in facility data over time can correspond to profile changes depending on the depth of the hole. In other words, facility data for each time section can correspond to the profile for each depth section of the hole.

The processor 120 may generate at least one factor based on real-time facility data. The processor 120 may generate at least one factor based on facility data for each time section or facility data for at least two time sections. At least one factor may include average values of facility data for each time section and values calculated by combining the average values of facility data for each time section.

According to the above, real-time facility data may include a measurement of signal intensity over time. The processor 120 may generate at least one factor using an average signal intensity of each time section and an average signal intensity of each of at least two time sections. According to one embodiment, the at least one factor may include an absolute factor that is the average signal intensity of each time section and a calculation factor obtained by calculating the average signal intensity of each of at least two time sections.

The calculation factor may include, for example, factors that are a ratio between the average signal intensities of at least two time sections. For example, the target process may include a plurality of steps with different process conditions. Each step may include at least one time section. The calculation factor may include first factors that are a ratio of an average signal intensity of each time section for each step of the target process to an average signal intensity of the first time section within the same step, second factors that are a ratio of the average signal intensity of each time section to an average signal intensity of the first time section of the first step of the target process, and third factors that are a ratio of an average signal intensity of the (n+1)th time section to an average signal intensity of the n th time section. The processor 120 may obtain the first factor for a specific time section by calculating a ratio of an average signal intensity of the specific time section to an average signal intensity of the first time section of a step including the specific time section. The processor 120 may obtain a second factor for a specific time section by calculating a ratio of an average signal intensity of the specific time section to an average signal intensity of the first time section of the first step of the target process. The processor 120 may obtain a third factor for a specific time section by calculating a ratio of an average signal intensity of the specific time section to an average signal intensity of a time section immediately before the specific time section.

As another example, the calculation factor may include factors that are a ratio of a sum of an average signal intensity of at least two time sections divided by an average signal intensity of a reference time section. The processor 120 may obtain factors for the specific time section by calculating a ratio of a sum of an average signal intensity of at least two time sections including a specific time section divided by an average signal intensity of a reference time section. The reference time section may be the first time section of each step of the target process, the first time section of the first step of the target process, or the time section immediately before the specific time section.

According to some embodiments, real-time facility data may include measurements based on location. For example, real-time facility data may include measurements based on location within a chamber or on a semiconductor wafer used in a target process. The processor 120 may obtain facility data for each region of the chamber or semiconductor wafer by dividing the real-time facility data according to the distance from a reference point (e.g., center) of the chamber or the semiconductor wafer. The processor 120 may generate at least one factor based on facility data for each region or facility data for at least two regions. At least one factor may be to quantify the process state for each region divided according to the distance from the reference point (e.g., center) of the chamber or semiconductor wafer. At least one factor may include average values of facility data in each region and values calculated by combining the average values of facility data in each region.

The measurement value according to the location may include a value measuring the intensity of the signal according to the location. The processor 120 may generate at least one factor using an average signal intensity of each region and an average signal intensity of each of at least two regions. According to one embodiment, the at least one factor may include an absolute factor that is the average signal intensity of each region and a calculation factor obtained by calculating the average signal intensity of each of the at least two regions. The calculation factor may include, for example, factors that are a ratio between the average signal intensities of at least two regions. As another example, the calculation factor may include factors that are a ratio of an average signal intensity in at least two regions divided by an average signal intensity in the reference region. The reference region may be, for example, a region including a reference point.

According to the above, the target process may include a plurality of processes. The processor 120 may generate at least one factor based on real-time facility data corresponding to a plurality of processes. At least one factor may include factors corresponding to each of a plurality of processes. For example, when the target process includes a first process and a second process, the processor 120 generates at least one factor based on real-time facility data corresponding to the first process, and generates at least one factor corresponding to the second process. For example, the first process and the second process may be sub-processes of the process of forming one structure. As another example, the first process and the second process may each be processes for forming different structures.

In one embodiment, the processor 120 may obtain the profile of the hole based on at least one factor. At least one factor may quantitatively indicate the degree of etching for each depth section of the hole. The depth sections of the hole may respectively correspond to the time sections of the target process. For example, the processor 120 may quantitatively determine the relative degree of etching (e.g., etch amount) between a plurality of time sections based on at least one factor for each time section. The processor 120 may determine a critical dimension (or diameter) for each depth section of the hole based on a quantified degree of etching for each time section of the target process. The processor 120 may obtain (or predict) a profile of the hole based on the critical dimension determined for each depth section of the hole. The profile information of the hole may include information about changes in the critical dimension of the hole according to (i.e., as a function of) depth.

The processor 120 may predict a defect index of the target process based on at least one factor. For example, the processor 120 may determine the defect index based on the degree to which at least one factor differs from values specified for each factor. Values specified for each factor may be stored in the memory 110, for example. In one embodiment, the value specified for each factor may be a value estimated for each factor according to the process condition in order for the profile of the hole to be formed as designed. For example, the processor 120 may determine the defect index to be higher, as the difference between the factors and the values specified for each factor is larger. The processor 120 can determine the defect index to be lower, as the difference between the factors and the values specified for each factor is smaller. As another example, the processor 120 may determine the defect index to be higher as the factor becomes larger, but it is not limited to this. Depending on the factor, the processor 120 may determine the defect index to be higher as the factor becomes smaller.

According to the above, the target process may include a plurality of processes. The processor 120 may predict a defect index related to defects occurring due to a plurality of processes based on at least one factor generated based on real-time facility data corresponding to the plurality of processes.

For example, when the target process includes a first process and a second process, the processor 120 generates at least one factor based on each of the real-time facility data corresponding to the first process and the real-time facility data corresponding to the second process, and predict a defect index related to defects occurring due to the first process and the second process based on the generated at least one factor.

For example, the first process and the second process may be sub-processes of the process of forming one structure. In this case, defects occurring due to the first process and the second process may mean defects occurring with only one structure. As another example, the first process and the second process may each be processes for forming different structures. In this case, defects that occur due to the first process and the second process may mean defects that occur when a plurality of structures influence each other.

In the above-described example, the target process includes two processes, but it is not limited to this. Even when the target process includes three or more processes, the processor 120 generates at least one factor based on real-time data corresponding to a plurality of processes and predicts defects based on the at least one factor. The method of generating the at least one factor and predicting defects based on the at least one factor may be applied in the same or a similar manner as the above-described method, although embodiments are not limited thereto.

In one embodiment, the processor 120 may predict the defect index of the target process based on the profile of the hole. According to one embodiment, the processor 120 may obtain the profile of the hole based on at least one factor. The profile information of the hole may include information about changes in the critical dimension of the hole according to depth. For example, the processor 120 may determine the defect index based on the degree to which the critical dimension for each depth section deviates from the range specified for each depth section. Ranges specified for each depth section may be stored in the memory 110, for example. Here, the range specified for each depth section may be a range between minimum and maximum values of the critical dimension designed for each depth section of the hole to enable normal electrical operation. For example, if the critical dimension of a depth section is greater than the maximum value of the range specified for that depth section, the structure formed in the hole may contact another adjacent structure in that depth section. As another example, if the critical dimension of a depth section is less than the minimum value of the range specified for that depth section, the structure formed in the hole may itself not operate properly electrically. The processor 120 may determine the defect index to be higher, as the degree to which the critical dimension for each depth section deviates from the range specified for each depth section is greater. The processor 120 may determine the defect index to be high when the critical dimension for each depth section is out of the range specified for each depth section, and may determine the defect index to be low when the critical dimension for each depth section is within the range specified for each depth section. The processor 120 may determine the defect index to be lower, as the degree to which the critical dimension for each depth section deviates from the range specified for each depth section is smaller.

According to one embodiment, the processor 120 may identify a time section of a target process and a depth section of a hole where defects are predicted to occur based on at least one factor. The processor 120 may determine the time section of the target process corresponding to the factor that increases the defect index among at least one factor as the time section in which defect occurrence is predicted. The processor 120 may determine the depth section of the hole corresponding to the time section of the target process corresponding to the factor that increases the defect index among the plurality of depth sections as the depth section where defects are predicted to occur. Alternatively, the processor 120 may determine the depth section of a hole that increases the defect index among the plurality of depth sections as the depth section where defects are predicted to occur. For example, the processor 120 may determine a depth section in which the critical dimension of a hole is out of (i.e., beyond) a specified range among a plurality of depth sections as a depth section in which defects are predicted to occur.

According to some embodiments, at least one factor may include factors generated for each region divided according to a distance from a reference point of the semiconductor wafer. The processor 120 may identify a region on the semiconductor wafer where defects are predicted to occur based on the at least one factor. The processor 120 may determine a region on the semiconductor wafer corresponding to a factor that increases the defect index among the plurality of regions as a region where defects are predicted to occur.

The processor 120 may generate a process defect prediction model based on the at least one factor, process information of the target process, and an actual defect index for each wafer. Process information of the target process may include a process condition, and the process condition may include information such as source gas type, temperature, and pressure of the etch chamber. The actual defect index for each wafer may refer to the defect index obtained through electrical property evaluation for a wafer that has completed the entire process including the target process.

The processor 120 may generate training data using at least one factor and process information as input and the actual defect index for each wafer as the correct answer corresponding to the input. For example, the processor 120 may standardize data corresponding to process information and use it as training data. For example, the processor 120 may perform hierarchical sampling and use sampled data as training data.

The processor 120 may generate a process defect prediction model by training a machine learning model using the generated training data. The machine learning model may be, for example, a transformer, but is not limited to this, and the machine learning model that is the subject of training may be changed to various artificial neural network models.

The processor 120 may predict the defect index for subsequent wafers based on the process defect prediction model. The processor 120 inputs at least one factor obtained by performing a target process on subsequent wafers and process information of the target process for subsequent wafers into the trained process defect prediction model to determine the defect index for subsequent wafers.

The processor 120 may determine the defect level of subsequent wafers based on the predicted defect index for subsequent wafers. For example, the processor 120 may determine that the defect level is serious or otherwise unacceptable if the predicted defect index is greater than or equal to a threshold value, and may determine that the defect level is good if the predicted defect index is less than the threshold value. In the above-described example, the processor 120 divides the defect level into two levels, but the present invention is not limited to this, and the defect level may be further divided into three levels or more.

For example, the processor 120 may label the defect level determined for each wafer and store the labeling information in the memory 110. The processor 120 may identify the determined defect level for subsequent wafers based on labeling information stored in the memory 110.

The processor 120 may determine the process flow for subsequent wafers based on the defect level determined for the subsequent wafers. The processor 120 may determine a subsequent process schedule for each wafer based on the defect level determined for subsequent wafers. The processor 120 may decide to perform a subsequent process on a wafer with a good level of defect first rather than a wafer with a serious level of defect.

The processor 120 may determine whether to proceed with the target process based on the predicted defect index. For example, the processor 120 may determine to stop the target process if the predicted defect index is greater than or equal to a threshold value, and may determine to continue performing the target process for a subsequent wafer if the predicted defect index is less than the threshold value.

The processor 120 may transmit a control signal to a facility control device 201 through the communication circuit 130 based on whether or not to proceed with the target process. For example, when the processor 120 decides to stop the target process, it may transmit a stop signal to the facility control device 201. For example, if the processor 120 determines to continue performing the target process, it may transmit an operation continuation signal to the facility control device 201.

The processor 120 may extract a factor that affects the predicted defect index among the at least one factor based on the fact that the predicted defect index is greater than or equal to a threshold value. Hereinafter, a factor affecting the predicted defect index may be referred to as a defect-causing factor. For example, the processor 120 may extract, among the at least one factor, a factor that is significantly different from a value specified for each factor as a defect-causing factor.

The processor 120 may determine a cause of a defect and a process condition for subsequent wafers based on the extracted defect-causing factor. The processor 120 may identify a material associated with the defect-causing factor. The processor 120 may identify whether the defect-causing factor is greater or less than a specified value. The processor 120 may identify which of the plurality of time sections of the target process the defect-causing factor corresponds to. The processor 120 can identify which of the plurality of regions on the semiconductor wafer the defect-causing factor corresponds to. For example, the processor 120 may determine a cause of the defect based on information about a material associated with the defect-causing factor, whether the defect-causing factor is greater or less than a specified value, information about a time section corresponding to the defect-causing factor, and/or information about a region on a semiconductor wafer corresponding to the defect-causing factor. As another example, information on the causes of defects related to each factor organized by factor may be stored in the memory 110, and the processor 120 may identify the cause of the defect corresponding the defect-causing factor based on the defect cause information for each factor stored in the memory 110.

The processor 120 may determine the process condition for a subsequent wafer based on the process condition of the target process step including the time section corresponding to the defect-causing factor and the cause of the defect. The processor 120 may change the process condition related to the cause of the defect among process conditions of the step of the target process that includes the time section corresponding to the defect-causing factor to be different from the existing process condition. For example, if the cause of the defect is high temperature, the processor 120 may change the process condition for the subsequent wafer to be lower than the temperature of the existing process condition of the step of the target process that includes the time section corresponding to the cause of the defect.

The processor 120 may variously change the process condition related to the cause of defects, perform a target process on subsequent wafers based on the variously changed process condition, and predict the defect index for subsequent wafers that have completed the target process. By repeating the process, the processor 120 may obtain an optimal condition for the target process.

The processor 120 may transmit defect prediction information including the predicted defect index and information on the time section of the target process in which defect occurrence is predicted to a yield management system 202 through the communication circuit 130. The processor 120 may transmit information about the defect index predicted for each wafer to the yield management system 202 through the communication circuit 130. The processor 120 may transmit defect prediction information to the yield management system 202 through the communication circuit 130. The defect prediction information may include, for example, information about the time section of the target process where defects are predicted to occur and the depth section of the hole where defects are predicted to occur. Defect prediction information may include, for example, information about a region on a semiconductor wafer where defects are predicted to occur. The defect prediction information may include, for example, profile information of the hole. Defect prediction information may include, for example, information about the cause of the defect and the changed process condition for subsequent wafers. The defect prediction information may include, for example, information about whether to proceed with the target process and a schedule for subsequent processes for wafers that have completed the target process. The defect prediction information may include a combination of the above-described examples, but is not limited thereto and may further include other information in addition to (or in substitution of) the above-described examples.

The yield management system 202 may visualize and output the predicted defect index and defect prediction information for each wafer received from the electronic device 101. Engineers can receive the predicted defect index and the defect prediction information for each wafer immediately after the target process through the yield management system 202.

The communication circuit 130 can communicate with an external electronic device through a wired or wireless communication network. For example, the communication circuit 130 may establish a communication connection between the electronic device 101 and the facility control device 201 and/or the yield management system 202.

The communication circuit 130 may transmit signals, data, and/or information stored in the memory 110 or processed by the processor 120 to an external electronic device. For example, the communication circuit 130 may transmit a facility control signal to the facility control device 201 according to whether to proceed with the target process. Whether to proceed with the target process may be determined based on the predicted defect index.

As another example, the communication circuit 130 may transmit the predicted defect index and the defect prediction information to the yield management system 202. For example, the defect prediction information may include information about the time section of the target process, the depth section of the hole, and/or the region on the semiconductor wafer where defects are predicted to occur. For example, the defect prediction information may include profile information of the hole. For example, the defect prediction information may include the cause of the defect. For example, the defect prediction information may include the changed process condition for subsequent wafers. For example, the defect prediction information may include the information about whether to proceed with the target process, and/or a schedule for subsequent processes for wafers that have completed the target process.

The communication circuit 130 may receive data from an external electronic device. For example, the communication circuit 130 may receive real-time facility data directly from the facility (or sensors of the facility) or through a server. Real-time facility data received through the communication circuit 130 may be stored in the memory 110.

In FIG. 2, the electronic device 101 is shown as including a memory 110, a processor 120, and a communication circuit 130, but is not limited thereto. In some embodiments, the electronic device 101 may further include an input/output device such as a display. For example, the electronic device 101 may directly output the predicted defect index and the defect prediction information through the display.

In the above-described embodiment, the electronic device 101 is separated from the facility control device 201 and the yield management system 202, communicates through the communication circuit 130, and operates independently, but is not limited to this. In some embodiments, the electronic device 101 may be integrated with facility control device 201 and/or the yield management system 202 to operate as a single electronic device.

According to one embodiment, the electronic device 101 may use real-time facility data obtained while the target process is in progress to generate at least one quantified factor that can represent the process state (e.g., profile of a hole) for each time section, and predict the defect index based on the at least one factor. Accordingly, the electronic device 101 of one embodiment can predict defects in the target process with high accuracy in a non-destructive manner for the entire quantity immediately after the target process.

According to some embodiments, the electronic device 101 may further generate at least one factor that quantifies the process state for each region divided according to the distance from the reference point of the chamber or semiconductor wafer used in the target process based on real-time facility data, and predict the defect index based on the at least one factor. Accordingly, the electronic device 101 of some embodiments may further predict a location where defects are predicted to occur (e.g., a region on a semiconductor wafer).

According to one embodiment, the electronic device 101 may extract defect-causing factors that increase the defect index and determine process conditions for subsequent wafers based on the defect-causing factors. Accordingly, the electronic device 101 of one embodiment can diagnose the cause of defects and derive improvement plans immediately after the target process, shortening the product development period and shortening the verification period of a new facility when expanding the facility.

According to one embodiment, the electronic device 101 may determine the defect level of wafers that have completed the target process based on the predicted defect index, and determine a subsequent process progress schedule for each wafer according to the defect level of the wafers. Accordingly, the electronic device 101 of one embodiment can efficiently manage the process flow of wafers.

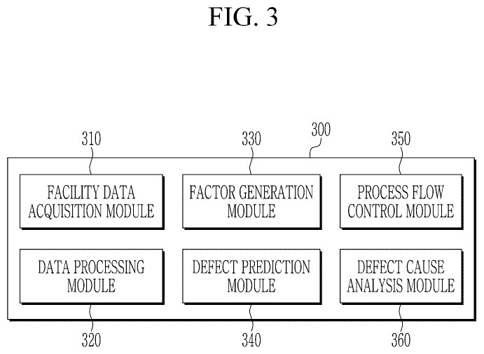

Below, with reference to FIG. 3, a program module executed by an electronic device according to an embodiment will be described.

FIG. 3 is a block diagram of an example program module 300 executed by an electronic device according to an embodiment of the inventive concept. According to one embodiment, the program module 300 may be a set of instructions stored in the memory 110 of the electronic device 101 of FIG. 2. Hereinafter, operations performed by each module of the program module 300 may be operations performed by the electronic device 101 as the corresponding module is executed by the processor 120 shown in FIG. 2.

Referring to FIG. 3, the program module 300 includes a facility data acquisition module 310, a data processing module 320, a factor generation module 330, a defect prediction module 340, a process flow control module 350, and a defect cause analysis module 360.

The facility data acquisition module 310 may be configured to acquire real-time facility data while the target process is in progress. In one embodiment, the target process may include etching a hole on a semiconductor wafer. However, the target process is not limited to the etching process and may include, for example, a deposition process or an annealing process. Additionally, the target process is not limited to a process of forming a hole, and may include a process of forming a structure other than a hole (e.g., a metal layer or an interface). In one embodiment, the target process may include a plurality of processes. The plurality of processes may include sub-processes included in the process of forming one structure, or may include processes of forming each of the plurality of structures.

Real-time facility data may be values measured in real time by various sensors in the facility. For example, the facility data acquisition module 310 may be configured to receive real-time facility data from the facility or at least one sensor of the facility, or to receive real-time data from an external server separate from the facility and to store such real-time data in memory (e.g., memory 110 in FIG. 2).

According to one embodiment, the real-time facility data may include a first measurement value indicating a change in signal intensity over time and/or a second measurement value indicating a change in signal intensity depending on the wavelength. Real-time facility data may include, for example, optical emission spectroscopy (OES) data and fault detection and classification (FDC) data.

However, real-time facility data is not limited to measurement values according to time and/or measurement values according to wavelength, and may include measurement values according to location and/or measurement values according to frequency. Real-time facility data can include a variety of continuous measurements. According to some embodiments, real-time facility data may include measurements representing changes in the intensity of a signal depending on location (e.g., location within a chamber or location on a semiconductor wafer).

The data processing module 320 may be configured to correct, standardize, normalize, and/or smooth the real-time facility data, although the data processing module 320 is not limited to these actions. The correction may include, but is not limited to, facility noise correction. The data processing module 320 may standardize the first measurement value by dividing a value that changes during the target process by a constant value during the target process. For example, if the real-time facility data is OES data, the data processing module 320 may standardize the first measurement value of the etch by-product by dividing it by the first measurement value of the inert gas.

The data processing module 320 may smooth the first measurement value. For example, the data processing module 320 may smooth the first measurement value using a moving average. The data processing module 320 may standardize the first measurement value and smooth the standardized first measurement value.

The data processing module 320 may perform self wavelength correction on the second measurement value. The data processing module 320 may normalize the second measurement value by dividing the average signal intensity in the first wavelength range by the average signal intensity in the second wavelength range.

For example, when the real-time facility data is OES data, the real-time facility data may include the first measurement value and the second measurement value. For example, when the real-time facility data is OES data, the data processing module 320 may perform normalization on the second measurement value and then standardization and smoothing on the first measurement value described above.

For example, when the real-time facility data is FDC, the real-time facility data may include the first measurement value and not the second measurement value. The data processing module 320 may perform normalization and smoothing on the first measurement value.

The factor generation module 330 may be configured to generate at least one factor that quantifies the process state for each time section of the target process based on the real-time facility data processed by the data processing module 320. For example, if the target process is a process of etching a hole, the process state for each time section may include the degree of etching (e.g., etching amount) for each time section. Depending on the degree of etching, the critical dimension of the hole and the profile of the hole may vary. As time passes after starting the target process, the depth of the hole may increase. Accordingly, the plurality of time sections of the target process may respectively correspond to the plurality of depth sections of the hole.

The factor generation module 330 may, in some embodiments, divide real-time facility data into a plurality of time sections. For example, the factor generation module 330 may divide real-time facility data so that a plurality of time sections have the same time interval. Facility data for each time section can correspond to the profile for each depth section of the hole. The factor generation module 330 may generate at least one factor based on facility data for each time section or facility data for at least two time sections. At least one factor may include average values of facility data for each time section and values calculated by combining the average values of facility data for each time section. Real-time facility data may include measurements of signal intensity over time. The factor generation module 330 may generate at least one factor using the average signal intensity of each time section and the average signal intensity of each of at least two time sections. At least one factor may include an absolute factor that is the average signal intensity of each time section and a calculation factor obtained by calculating the average signal intensity of each of at least two time sections.

Meanwhile, the target process may include a plurality of steps with different process conditions. Each step may include at least one time section.

For example, the factor generation module 330 may generate a first factor that is a ratio of the average signal intensity of each time section for each step of the target process to the average signal intensity of the first time section within the same step. The factor generation module 330 may generate a second factor that is a ratio of the average signal intensity of each time section to the average signal intensity of the first time section of the first step of the target process. The factor generation module 330 may generate a third factor that is the ratio of the average signal intensity of the (n+1)th time section to the average signal intensity of the n th time section. The factor generation module 330 may obtain the first factor, the second factor, and the third factor for each time section.

The above-described first factor, second factor, and third factor may be examples of calculation factors that are ratios between the average signal intensities of at least two time sections. However, the calculation factors are not limited to the examples described above. As another example, the calculation factors may include factors that are a ratio of the sum of the average signal intensity of at least two time sections divided by the average signal intensity of the reference time section. The factor generation module 330 may calculate the ratio of the sum of the average signal intensity of at least two time sections including the specific time section divided by the average signal intensity of the reference time section to obtain factors for the specific time section. The reference time section may be the first time section of each step of the target process, the first time section of the first step of the target process, or the time section immediately before the specific time section.

The factor generation module 330 may obtain facility data for each region of the chamber or semiconductor wafer by dividing the real-time facility data according to the distance from the reference point (e.g., center) of the chamber or semiconductor wafer. The facility data for each region may include a measurement of the signal intensity in each region. The factor generation module 330 may generate at least one factor using the average signal intensity of each region and the average signal intensity of each of at least two regions. The at least one factor may include an absolute factor that is the average signal intensity of each region and a calculation factor obtained by calculating the average signal intensity of each of the at least two regions. The calculation factors may include, for example, factors that are ratios between the average signal intensities of at least two regions. As another example, the calculation factors may include factors that are ratios of the average signal intensity in at least two regions divided by the average signal intensity in the reference region. For example, the reference region may be a region including a reference point.

The factor generation module 330 may generate at least one factor based on real-time facility data corresponding to a plurality of processes included in the target process. For example, when the target process includes a first process and a second process, the factor generation module 330 may generate at least one factor based on real-time facility data corresponding to the first process and generate at least one factor based on real-time facility data corresponding to the second process.

The defect prediction module 340 may be configured to predict the defect index of the target process based on the at least one factor. For example, the defect prediction module 340 may determine the defect index based on the degree to which the at least one factor differs from values specified for each factor. The values specified for each factor may be stored in the memory (e.g., memory 110 in FIG. 2). For example, the defect prediction module 340 may determine the defect index to be high as the difference between the factors and the values specified for each factor is large, and determine the defect index to be low as the difference between the factors and the values specified for each factor is small. As another example, the defect prediction module 340 may determine the defect index to be higher as the factor is larger, or determine the defect index to be higher as the factor is smaller.

The defect prediction module 340 may predict a defect index related to defects occurring due to a plurality of processes based on at least one factor generated based on real-time facility data corresponding to the plurality of processes. For example, when the target process includes a first process and a second process, the defect prediction module 340 may generate at least one factor based on each of real-time facility data corresponding to the first process and real-time facility data corresponding to the second process, predict a defect index related to defects occurring due to the first process and the second process based on the at least one factor. Defects that occur due to the first process and the second process may include defects that occur with only one structure or defects that occur when a plurality of structures influence each other.

For example, when the target process includes a process of etching a hole, the defect prediction module 340 may obtain a profile of the hole based on the at least one factor. At least one factor for each time section can quantitatively indicate the degree of etching (e.g., etching amount) in the corresponding time section by comparing it with other time sections. For example, the degree of etch may be proportional to the critical dimension (or diameter). The defect prediction module 340 may determine a critical dimension for each depth section of the hole based on the at least one factor for each time section. The defect prediction module 340 may obtain the profile of the hole based on the critical dimension for each depth section of the hole.

The defect prediction module 340 may predict the defect index of the target process based on the profile of the hole. The profile information of the hole may include information about changes in the critical dimension of the hole according to (i.e., as a function of) depth. The defect prediction module 340 may determine the defect index according to the degree to which the critical dimension for each depth section deviates from the range specified for each depth section. The ranges specified for each section may be between prescribed minimum and maximum values of the critical dimension designed for each depth section of the hole to enable normal electrical operation. The ranges specified for each section may be stored, for example, in the memory (e.g., memory 110 in FIG. 2). For example, the defect prediction module 340 may determine a defect index high when the critical dimension for each depth section is out of the specified range for each depth section, and may determine a defect index low when the critical dimension for each depth section is within the specified range for each depth section. The defect prediction module 340 may determine a defect index to be higher as the degree to which the critical dimension for each depth section deviates from the specified range increases, and may determine a defect index to be lower as the degree to which the critical dimension for each depth section deviates from the specified range decreases, although embodiments are not limited thereto.

The defect prediction module 340 may identify the time section of the target process and depth section of the hole in which defect occurrence is predicted based on the at least one factor. The defect prediction module 340 may determine the time section of the target process corresponding to the factor that increases the defect index among the at least one factor as the time section in which defect occurrence is predicted. The defect prediction module 340 may determine the depth section of the hole corresponding to the time section in which defect occurrence is predicted to be the depth section in which defect occurrence is predicted. The defect prediction module 340 may determine a depth section having a critical dimension that increases the defect index among the plurality of depth sections as the depth section where defects are predicted to occur. For example, the defect prediction module 340 may determine a depth section in which the critical dimension of a hole is out of a specified range among a plurality of depth sections as the depth section where defects are predicted to occur.

The defect-prediction module 340 may identify a region on the semiconductor wafer where defects are predicted to occur based on at least one factor generated for each region divided according to the distance from the reference point of the semiconductor wafer. The defect-prediction module 340 may determine a region on the semiconductor wafer corresponding to a factor that increases the defect index among the plurality of regions as a region where defects are predicted to occur.

The defect-prediction module 340 may generate a process defect prediction model based on the at least one factor, process information of the target process, and an actual defect index for each wafer. The process information may include process conditions. The process conditions may include information such as source gas type, temperature, and pressure of the etch chamber. The actual defect index may be a defect index obtained through electrical property evaluation of a wafer that has completed the entire process.

The defect-prediction module 340 may generate training data using the at least one factor and the process information as input and the actual defect index for each wafer as the correct answer corresponding to the input. The defect prediction module 340 may standardize data corresponding to the process information. The defect prediction module 340 may generate data using the at least one factor and the standardized process information as input and the actual defect index for each wafer as the correct answer. The defect prediction module 340 may generate training data by performing hierarchical sampling on the generated data.

The defect prediction module 340 may generate a process defect prediction model by training a machine learning model using the training data. A machine learning model that is subject to training may include, for example, deep learning model based on artificial neural network, such as a transformer.

The defect prediction module 340 may predict the defect index for subsequent wafers based on the process defect prediction model. Here, subsequent wafers may refer to wafers that are input to the facility performing the target process after wafers used as training data for the process defect prediction model. The defect prediction module 340 inputs at least one factor obtained by performing a target process on each of the subsequent wafers and process information of the target process for each of the subsequent wafers into the learned process defect prediction model, the defect index for each can be predicted.

The defect prediction module 340 may determine the defect level for each wafer based on the predicted defect index. For example, the defect prediction module 340 may determine that the defect level is serious if the predicted defect index is greater than or equal to a first threshold value, and may determine that the defect level is good if the predicted defect index is less than the first threshold value. The defect prediction module 340 may label the defect level for each wafer.

The defect prediction module 340 may transmit information on the predicted defect index and the time section in which defects are predicted to occur to the yield management system (e.g., 202 in FIG. 2). The defect prediction module 340 may transmit information about the region on the semiconductor wafer where defects are predicted to occur to the yield management system (e.g., 202 in FIG. 2). The defect prediction module 340 may transmit profile information of the hole to the yield management system (e.g., 202 in FIG. 2). The defect prediction module 340 may transmit information about the depth section of the hole where defects are predicted to occur to the yield management system (e.g., 202 in FIG. 2). The depth section of the hole where defects are predicted to occur may correspond to the time section of the target process where defects are predicted to occur.

The process flow control module 350 may determine the process flow of subsequent wafers based on the labeled defect level. For example, the process flow control module 350 may determine to perform a subsequent process on a wafer with a good defect level first rather than a wafer with a serious (i.e., high) defect level.

The process flow control module 350 may determine whether or not to proceed with the target process based on the predicted defect index. For example, the process flow control module 350 may decide to stop the target process if the predicted defect index is equal to or greater than the second threshold value, and if the predicted defect index is less than the second threshold value, the process flow control module 350 may decide to continue the target process for the subsequent wafer. The second threshold value may be equal to or greater than the first threshold value.

The process flow control module 350 may transmit a control signal to the facility control device (e.g., 201 in FIG. 2) based on whether or not to proceed with the target process. For example, when the process flow control module 350 determines to stop the target process, it may transmit an operation stop signal to the facility control device (e.g., 201 in FIG. 2). If the process flow control module 350 determines to continue performing the target process, it may transmit an operation continuation signal to the facility control device (e.g., 201 in FIG. 2).

The process flow control module 350, in one or more embodiments, may transmit information about whether or not to proceed with the target process (e.g., stop or continue) and the subsequent process progress schedule for wafers that have completed the target process to the yield management system (e.g., 202 in FIG. 2).

The defect cause analysis module 360 may be configured to extract a factor (hereinafter referred to as a “defect-causing factor”) that caused, or at least influenced, the predicted defect index to exceed the threshold value among at least one factor. The defect cause analysis module 360 may extract as a defect-causing factor a factor that is significantly different from a value specified for each factor among at least one factor.

The defect cause analysis module 360 may determine the cause of the defect and process conditions for subsequent wafers based on the extracted defect-causing factors. Here, the subsequent wafer may refer to a wafer that is input into the facility performing the target process after the wafer for which the defect index is predicted. The defect cause analysis module 360 may determine a cause of defect based on information about materials related to the defect-causing factor, whether the defect-causing factor is greater than or less than a specified value, information about a time section corresponding to the defect-causing factor, and/or information about a region on the semiconductor wafer corresponding to the defect-causing factor. Alternatively, the defect cause analysis module 360 may identify the cause of defect corresponding to a defect-causing factor based on defect cause information for each factor stored in memory (e.g., memory 110 in FIG. 2). The defect cause information for each factor may include, for example, information about the cause of defects related to each factor.

The defect cause analysis module 360 may determine process conditions for a subsequent wafer based on the process conditions of the step of the target process including the cause of the defect and the time section corresponding to the defect-causing factor. The defect cause analysis module 360 may change the process conditions related to the cause of the defect among the process conditions of the target process step that includes the time section corresponding to the defect-causing factor. For example, if the cause of the defect is high temperature, the defect cause analysis module 360 may determine to lower the temperature among the process conditions of the target process step including the time section corresponding to the defect-causing factor.

The defect cause analysis module 360 may transmit information about the cause of defects and changed process conditions for subsequent wafers to the yield management system (e.g., 202 in FIG. 2).

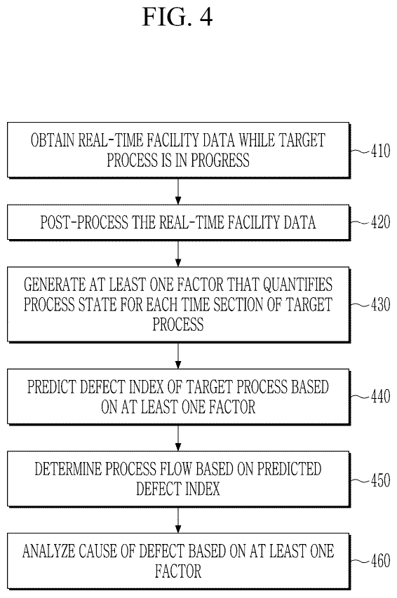

Hereinafter, a method of operating an electronic device according to an embodiment will be described with reference to FIGS. 4 to 7.

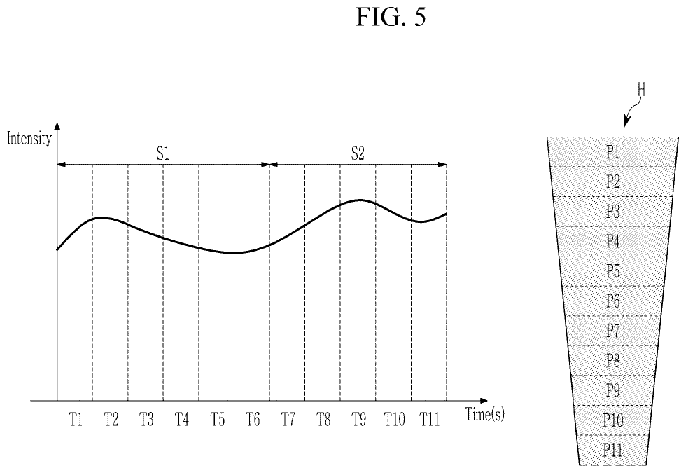

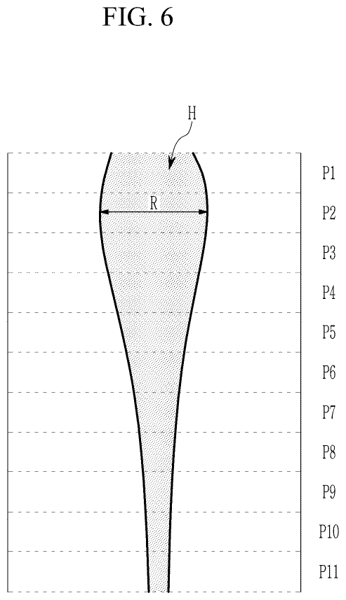

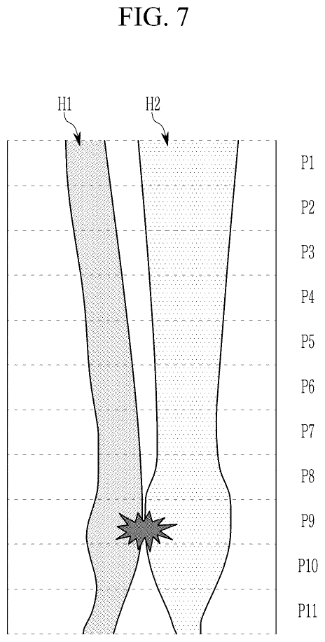

FIG. 4 is a flowchart showing an example method of operating an electronic device according to an embodiment. FIG. 5 is a diagram conceptually illustrating an example method in which an electronic device according to an embodiment generates at least one factor based on facility data for each time section. FIG. 6 is a diagram illustrating an example method by which an electronic device according to an embodiment obtains a profile of a hole based on at least one factor. FIG. 7 is a diagram illustrating an example method for an electronic device according to an embodiment to predict a defect index based on at least one factor.

Operations of the electronic device described later with reference to FIGS. 4 to 7 may be performed by the illustrative electronic device 101 of FIG. 2, according to one or more embodiments.

In operation 410, the electronic device may obtain real-time facility data while the target process is in progress. For example, the electronic device may receive real-time facility data from a facility performing a target process or at least one sensor of the facility through a communication circuit (e.g., communication circuit 130 of FIG. 2). As another example, the electronic device may receive real-time facility data through a communication circuit (e.g., communication circuit 130 in FIG. 2) from an external server where real-time facility data is stored. The external server may be an electronic device separate from the facility that performs the target process.

In one or more embodiments, the electronic device is configured to obtain real-time facility data while the target process for the semiconductor wafer is in progress. According to one embodiment, the target process may be a process of forming a structure (e.g., a hole) in a semiconductor wafer using plasma processing. Real-time facility data may include values measured in real time by sensors in the facility performing the target process. Real-time facility data may include, but is not limited to, optical emission spectroscopy (OES) data and fault-detection and classification (FDC) data, for example. Real-time facility data is measured over time for the same object and may include a variety of continuous measurement values.

Real-time facility data may include measurements representing changes in signal intensity over time, measurements representing changes in signal intensity over wavelength, measurements representing changes in signal intensity over location, and/or changes in signal intensity over frequency, although embodiments are not limited thereto. Hereinafter, the measurement value representing the change in signal intensity over time may be referred to as a first measurement value, and the measurement value representing the change in signal intensity depending on the wavelength may be referred to as a second measurement value. For example, OES data may include both the first measurement value and the second measurement value. For example, FDC data may include only the first measurement value.

In operation 420, the electronic device may post-process real-time facility data. For example, post-processing may include facility noise correction, standardization, normalization, and/or smoothing.

The electronic device may standardize the first measurement value by dividing a value that changes during the target process by a constant value during the target process. For example, the electronic device may standardize the first measurement value of the OES data by dividing the first measurement value of the etch by-product by the first measurement value of the inert gas.

The electronic device may smooth the first measurement value. For example, the electronic device may smooth the first measurement value using a moving average. The electronic device may first perform normalization on the first measurement value and then perform smoothing on the standardized first measurement value.

The electronic device may normalize the second measurement value by dividing an average signal intensity in a first wavelength range by an average signal intensity in a second wavelength range. The second wavelength range includes the first wavelength range and may be a wider wavelength range than the first wavelength range.

For example, for real-time facility data including both the first measurement value and the second measurement value, the electronic device may perform normalization on the second measurement value and then normalization and smoothing on the first measurement value.

In operation 430, the electronic device may generate at least one factor that quantifies the process state for each time section of the target process. Referring to FIG. 5, by way of example only, the electronic device may divide the post-processed real-time facility data into a plurality of time sections, T1 through T11. The real-time facility data in FIG. 5 may represent, for example, a change in signal intensity over time (in seconds) of OES data. Hereinafter, the description will focus on the case where the real-time facility data in FIG. 5 is OES data, but the contents described later can be applied equally or similarly to the other real-time facility data including measurement values according to time such as FDC data.

For example, the electronic device can divide OES data into 11 time sections. OES data may include the first to eleventh time sections (T1, T2, T3, T4, T5, T6, T7, T8, T9, T10, T11), although embodiments are not limited to eleven time sections. For example, the electronic device may divide OES data into more than 11 time sections (e.g., 12, 13, or more) or less than 11 time sections (e.g., 10, 9, or less). The electronic device may determine that the first to eleventh time sections (T1, T2, T3, T4, T5, T6, T7, T8, T9, T10, T11) have the same time interval (i.e., each time section T1 through T11 may be configured having the same duration (in seconds)), but is not limited to this. As another example, the electronic device may determine the interval of at least one time section to be different from another time section based on process information of the target process.

The target process may include, for example, a plurality of steps with different process conditions. A plurality of steps are performed sequentially at once by the same facility, but can be divided into different steps by changing at least some of the process conditions. According to the example of FIG. 5, the target process may include a first step S1 and a second step S2, and the process conditions of the first step S1 and the process conditions of the second step S2 may be different. Process conditions may include, for example, information such as source gas type, temperature, and pressure of the etch chamber.

For example, the first to sixth time sections (T1, T2, T3, T4, T5, T6) are included in the first step S1, and the seventh to eleventh time sections are included in the second step S2.

For example, a hole H may be formed on a semiconductor wafer through a target process. The hole H formed on the semiconductor wafer through the target process may be, for example, a hole with a high aspect ratio. According to the example of FIG. 5, the hole H may have a depth in the vertical direction. The hole H may include a first to an eleventh depth section (P1, P2, P3, P4, P5, P6, P7, P8, P9, P10, P11) in the etching order. That is, the first depth section P1 may be the depth section that is etched first (i.e., in the first time section T1), and the 11th depth section P11 may be the depth section that is etched last (i.e., in the 11th time section T11). The first to eleventh depth sections (P1, P2, P3, P4, P5, P6, P7, P8, P9, P10, P11) therefore correspond respectively to the first to eleventh time sections (T1, T2, T3, T4, T5, T6, T7, T8, T9, T10, T11).

The signal intensity of OES data may correspond to the amount of etch by-products. A large amount of etching by-products may mean a large amount of etching. The critical dimension (or diameter) of the hole H may be proportional to the etching amount. For example, as the signal intensity of the OES data increases, the critical dimension of the hole H may increase, and as the signal intensity of the OES data decreases, the critical dimension of the hole H may decrease.

The electronic device may generate at least one factor using the average signal intensity of each time section and the average signal intensity of each of at least two time sections. The electronic device can generate the average signal intensity as an absolute factor for each time section. The electronic device may calculate the average signal intensity of at least two time sections for each time section and generate a calculation factor.

For example, the electronic device may generate, for each time section, the ratio of the average signal intensity of the corresponding time section to the average signal intensity of the comparison reference time section as a calculation factor. The comparison reference time section may include, for example, the first time section of the first step of the target process, the first time section of each step of the target process, or the time section immediately preceding each time section.

The electronic device may generate first factors defined as a ratio of the average signal intensity of each time section for each step of the target process to the average signal intensity of the first time section within the same step. For example, the first factors may include ratios of the average signal intensity of each time section in the first step S1 to the average signal intensity of the first time section T1, which is the first time section of the first step S1. Each time section in the first step S1 is the first time section T1, the second time section T2, the third time section T3, the fourth time section T4, and the fifth time section T5, or the sixth time section T6. Additionally, the first factors may include ratios of the average signal intensity of each time section in the second step S2 to the average signal intensity of the seventh time section T7, which is the first time section of the second step S2. Each time section in the second step S2 is the 7th time section T7, the eighth time section T8, the ninth time section T9, the tenth time section T10, or the eleventh time section T11.

The electronic device may generate a second factor defined as a ratio of the average signal intensity of each time section to the average signal intensity of the first time section of the first step of the target process. For example, the second factors may include ratios of the average signal intensity of each time section to the average signal intensity of the first time section T1, which is the first time section of the first step of the target process. Each time section is the first time section T1, the second time section T2, the third time section T3, the fourth time section T4, the fifth time section T5, and the sixth time section T6, the seventh time section T7, the eighth time section T8, the ninth time section T9, the tenth time section T10, or the eleventh time section T11.

The electronic device may generate a third factor defined as the ratio of the average signal intensity of the (n+1)th time section to the average signal intensity of the n th time section. For example, the third factor may include a ratio of the average signal intensity of the second time section T2 to the average signal intensity of the first time section T1. Additionally, the third factor may include a ratio of the average signal intensity of the eleventh time section T11 to the average signal intensity of the tenth time section T10. In addition to the above-described ratios, the third factor may include a ratio of the average signal intensity of the preceding time section to the average signal intensity of the subsequent time section among two adjacent time sections.

The electronic device may obtain the first factor, the second factor, and/or the third factor for each of the first time section and the eleventh time section (T1, T2, T3, T4, T5, T6, T7, T8, T9, T10, T11).

The above-described first, second, and/or third factors are only examples of calculation factors, and the calculation factors are not limited to the above-described examples. As another example, the electronic device may generate, for each time section, a ratio of the sum of the average signal intensity of at least two time sections including the corresponding time section to the average signal intensity of the comparison reference time section as a calculation factor. The comparison reference time section may include, for example, the first time section of the first step of the target process, the first time section of each step of the target process, or the time section immediately preceding each time section.

As described above with reference to FIG. 5, the electronic device may divide real-time facility data into a plurality of time sections and generate at least one factor for each time section. However, the factors that the electronic device may generate are not limited to this. For example, real-time facility data may indicate changes in signal intensity depending on location (e.g., distance from a reference point) within a chamber or on a semiconductor wafer used in a target process. In this case, the electronic device may divide real-time facility data into a plurality of regions according to the distance from a reference point (e.g., center) within the chamber or on the semiconductor wafer. The electronic device may generate at least one factor for each region.

The electronic device may generate at least one factor using the average signal intensity of each region and the average signal intensity of each of at least two regions. The at least one factor may include an absolute factor that is the average signal intensity of each region and a calculation factor obtained by calculating the average signal intensity of each of the at least two regions. The calculation factors may include, for example, factors that are ratios between the average signal intensities of at least two regions. As another example, the calculation factors may include factors that are ratios of the average signal intensity in at least two regions divided by the average signal intensity in the reference region. For example, the reference region may be a region including a reference point.

Referring again to FIG. 4, in operation 440, the electronic device may predict the defect index of the target process based on the at least one factor. The electronic device may determine the defect index based on the degree to which at least one factor differs from a value specified for each factor. For example, the value specified for each factor may be a value estimated for each factor according to the process conditions in order for the profile of the hole to be formed as designed. For at least one factor for each time section, a value designated for each factor may be stored in the memory (e.g., memory 110 in FIG. 2) of the electronic device. For example, the electronic device may determine the defect index to be higher as the difference between the factors and the values specified for each factor is greater, and the defect index may be determined to be lower as the difference between the factors and the values specified for each factor is smaller. As another example, the electronic device may determine the defect index to be higher as the factor is larger, or determine the defect index to be lower as the factor is smaller.

The electronic device may quantify the relative process state (e.g., degree of etching) between a plurality of time sections based on at least one factor for each time section. Referring to FIG. 5, the electronic device may determine the critical dimension for each depth section of the hole H based on the degree of etching (e.g., etching amount) quantified for each time section. The electronic device may determine the critical dimension of each depth section corresponding to each time section based on at least one factor for each time section. For example, the electronic device may determine the critical dimension of the first depth section P1 corresponding to the first time section T1 based on at least one factor for the first time section T1. The electronic device can determine the critical dimensions of the first depth section P1 to the eleventh depth section P11 using the above-described method.

The electronic device may obtain the profile of the hole H based on the critical dimension for each depth section of the hole H. FIG. 6 is an example of a profile of a hole H acquired by an electronic device. Referring to FIG. 6, the electronic device may predict the profile of the hole H based on the critical dimensions of the first depth section P1 to the eleventh depth section P11 of the hole H. The electronic device may determine the defect index to be high when the critical dimension R for each depth section of the hole H is out of (i.e., exceeds) the range specified for each depth section. The electronic device may determine the defect index to be low when the critical dimension R for each depth section of the hole H is within a range specified for each depth section. The electronic device may determine the defect index to be higher as the degree to which the critical dimension R for each depth section of the hole H deviates from the range specified for each depth section is greater.

The specified range for the critical dimensions of the hole H per depth section can be a range between the minimum and maximum values of the critical dimensions designed by depth section of the hole, in order to enable normal electrical operation, this range may be stored in the memory (110 in FIG. 2) of the electronic device. For example, if the critical dimension of a hole H in a specific depth section is greater than the maximum value of the range specified for that depth section, the hole H may come into contact with another adjacent hole, thereby electrically affecting it.

Referring to FIG. 7, a plurality of holes H including first hole H1 and second hole H2 adjacent to each other in a horizontal direction, parallel to the upper surface of the wafer, may be formed through a target process. The electronic device may generate at least one factor for each time section based on real-time facility data acquired while forming the first hole H1. The electronic device may generate at least one factor for each time section based on real-time facility data acquired while forming the second hole H2. For example, at least one factor for the ninth time section T9 of the first hole H1 and/or the second hole H2 may be greater than or equal to a specified value. In the electronic device, at least one factor for the ninth time section T9 of the first hole H1 and/or the second hole H2 may be greater than or equal to a specified value.

The electronic device may determine the critical dimension for each depth section of the first hole H1 based on at least one factor for each time section. The electronic device may determine the critical dimension for each depth section of the second hole H2 based on at least one factor for each time section. For example, the critical dimension of the ninth depth section P9 of the first hole H1 and/or the second hole H2 may be greater than the maximum value of the specified range.

At least one factor for the ninth time section T9 of the first hole H1 and/or the second hole H2 is greater than or equal to a specified value, or the critical dimension of the ninth depth section P9 of the first hole H1 and/or the second hole H2 is greater than the maximum value of the specified range, the electronic device may predict the defect index to be high.

The electronic device may obtain the profile of the first hole H1 based on the critical dimension for each depth section of the first hole H1. The electronic device may obtain the profile of the second hole H2 based on the critical dimension for each depth section of the second hole H2. Based on the profile of the first hole H1 and the profile of the second hole H2, the electronic device determines whether the adjacent first hole H1 and the second hole H2 are in contact with each other in the ninth depth section P9, and whether defects may occur. For example, if either the adjacent first hole H1 or the second hole H2 is a contact structure (e.g., CT in FIG. 1) of a NAND flash memory device, the predicted defect may be a contact defect. As another example, when the adjacent first hole H1 and the second hole H2 are dummy contact structures (e.g., DCT in FIG. 1) of a NAND flash memory device, the predicted defect may be a word line disconnection defect.

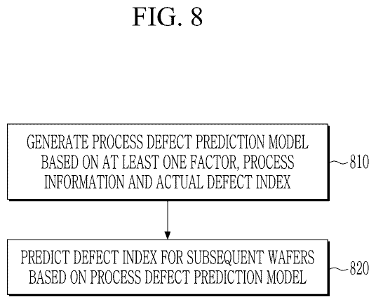

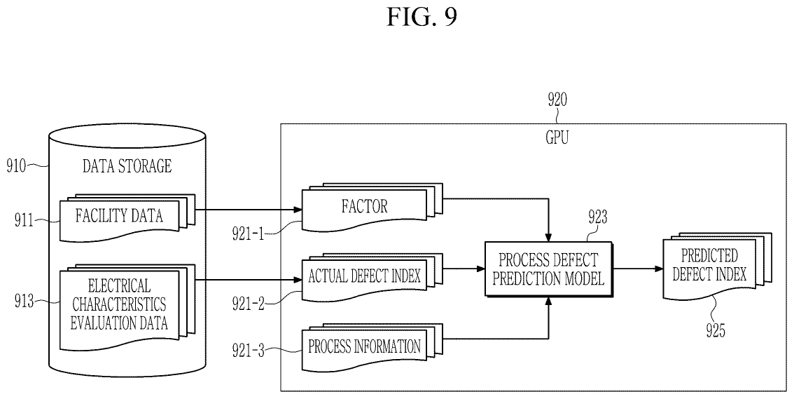

According to the above, the electronic device may predict the defect index of the target process based on at least one factor, but is not limited to this. As another example, the electronic device may generate a process defect prediction model by training a machine learning model using at least one factor, and predict a defect index for a subsequent wafer based on the process defect prediction model. This will be described in more detail with reference to FIGS. 8 and 9.

Referring again to FIG. 4, in operation 450, the electronic device may determine a process flow based on the predicted defect index. The electronic device can determine the defect level of each wafer based on the predicted defect index for each wafer. The electronic device may determine the defect level of a wafer to be serious if the predicted defect index of the wafer is greater than or equal to a first threshold value. The electronic device may determine the defect level of a wafer to be good when the predicted defect index of the wafer is less than the first threshold value. The electronic device may decide to perform a subsequent process on a wafer with a good defect level first rather than a wafer with a serious defect level. The electronic device can determine a subsequent process schedule for each wafer based on the defect level for each wafer.

The electronic device may determine to stop the target process for a subsequent wafer if the predicted defect index of any wafer is greater than or equal to a second threshold value. The electronic device may determine to continue performing the target process on a subsequent wafer if the predicted defect index of a wafer is less than the second threshold value. The second threshold may be equal to or greater than the first threshold value.

In operation 460, the electronic device may analyze the cause of the defect based on at least one factor. The electronic device may perform the operation 460 when the predicted defect index is greater than or equal to a threshold value or the defect level is determined to be serious (i.e., having a defect level that is above a prescribed acceptable number of defects).

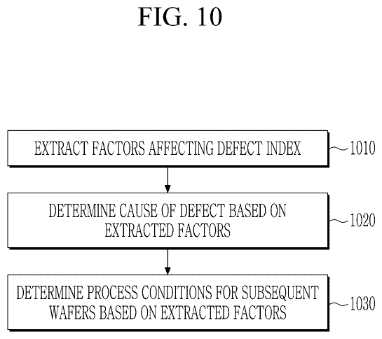

The electronic device may extract at least one factor that influences the predicted defect index to exceed a threshold value. The electronic device can determine the cause of the defect based on the extracted factors. The electronic device can determine process conditions for subsequent wafers based on the extracted factors. More details about the operation 460 will be described later with reference to FIG. 10.

An electronic device according to an embodiment may generate at least one quantified factor that can represent the process state (e.g., hole profile) for each time section using real-time facility data obtained while the target process is in progress, and may predict a defect index based on at least one factor. Accordingly, the electronic device may predict defects in the target process with high accuracy in a non-destructive manner for the entire quantity immediately after the target process.

The electronic device according to one embodiment may determine the defect level of wafers that have completed the target process based on the predicted defect index and determine a subsequent process progress schedule for each wafer according to the defect level of the wafers. Accordingly, the electronic device may efficiently manage the process flow of the wafers.

Hereinafter, a method of operating an electronic device according to an embodiment will be described with reference to FIGS. 8 and 9.

FIG. 8 is a flowchart showing an example method of operating an electronic device according to an embodiment. FIG. 9 is a diagram illustrating an example method for an electronic device according to an embodiment to predict a defect index using a process defect-prediction model.

Operations of the electronic device described later with reference to FIGS. 8 and 9 may be performed by the illustrative electronic device 101 of FIG. 2.

In an operation 810, the electronic device may generate a process defect prediction model based on at least one factor, process information, and an actual defect index. For example, with reference to FIG. 9, the electronic device may include a data storage 910 and a graphic processing unit (GPU) 920. The data storage 910 may correspond to memory 110 of FIG. 2. The GPU 920 may correspond to processor 120 of FIG. 2. The GPU 920 may be one of at least one processor of the electronic device.

The GPU 920 may obtain facility data 911 from the data storage 910. The facility data 911 may be real-time facility data including values measured by various sensors of a facility.

The GPU 920 may pre-process the facility data 911. The method by which the GPU 920 pre-processes the facility data 911 may be the same as the post-processing method of real-time facility data of an electronic device described above with reference to the operation 420 of FIG. 4, and redundant descriptions will be omitted.

The GPU 920 may generate at least one factor 921-1 based on the pre-processed facility data 911. The GPU 920 may divide the pre-processed facility data 911 into a plurality of time sections and generate at least one factor 921-1 for each time section. The method by which the GPU 920 generates at least one factor 921-1 for each time section may be the same as the method of generating factors of the electronic device described above with reference to operation 430 of FIG. 4, and duplicate descriptions will be omitted.

GPU 920 may obtain electrical characteristics evaluation data 913 from data storage 910. The electrical characteristics evaluation data 913 may include the results of electrical property evaluation on a wafer that has completed the entire process including the target process. The GPU 920 may obtain the actual defect index 921-2 based on the electrical characteristics evaluation data 913.

The GPU 920 may standardize data corresponding to process information 921-3. The process information 921-3 may include process conditions of the target process. Process conditions may include information such as, for example, source gas type, temperature, and pressure of the etch chamber. For example, the GPU 920 may obtain the process information 921-3 from the data storage 910, but the process is not limited thereto.

The GPU 920 may generate training data based on at least one factor 921-1, the actual defect index 921-2, and/or the process information 921-3. The GPU 920 may generate data using at least one factor 921-1 and standardized process information 921-3 as inputs and the actual defect index 921-2 for each wafer as the correct answer. The GPU 920 may generate training data by performing hierarchical sampling on the generated data.

The GPU 920 can train a process defect prediction model 923 using training data. The process defect prediction model 923 may be a machine learning model. The process defect prediction model 923 may include, for example, a transformer, but is not limited thereto, and may include a deep learning model based on various artificial neural networks.

Referring again to FIG. 8, in operation 820, the electronic device may predict a defect index for a subsequent wafer based on a process defect prediction model (e.g., 923 in FIG. 9). Referring to FIG. 9, the GPU 920 may obtain a predicted defect index 925 for a subsequent wafer based on the trained process defect prediction model 923.

The GPU 920, in one or more embodiments, may be configured to pre-process the facility data 911 obtained while the target process is being carried out for each subsequent wafer, divide the pre-processed facility data 911 into a plurality of time sections, and generate at least one factor 921-1 for each time section.

The GPU 920 may obtain process information 921-3 of the target process for each subsequent wafer. The GPU 920 may obtain a predicted defect index 925 for each of the subsequent wafers by inputting at least one parameter 921-1 and process information 921-3 for each time section of the subsequent wafers into a trained process defect-prediction model 923.

Below, with reference to FIG. 10, a method of operating an electronic device according to an embodiment of the inventive concept will be described.

FIG. 10 is a flowchart showing an example method of operating an electronic device according to an embodiment.

The operations of the electronic device described later with reference to FIG. 10 may be performed by the electronic device 101 of FIG. 2. The operations in FIG. 10 may be specific operations of operation 460 in FIG. 4. For example, the electronic device may perform the operations of FIG. 10 after performing operations 410 to 450 of FIG. 4.

In operation 1010, the electronic device may extract factors affecting the defect index. Electronic devices may extract factors that increase the defect index as defect-causing factors. The electronic device may extract, among at least one factor, a factor that is significantly different from the value specified for each factor as a defect-causing factor. The electronic device may obtain at least one factor through operation 430 of FIG. 4, and redundant description will be omitted. The value specified for each factor may be a value that the electronic device compares with at least one factor in operation 440 of FIG. 4 to predict the defect index of the target process.

In operation 1020, the electronic device may determine the cause of the defect based on the extracted factors. For example, the electronic device may identify information about the material related to the defect-causing factor, whether the defect-causing factor is greater or less than the specified value, the time section corresponding to the defect-causing factor, and/or the region on the semiconductor wafer corresponding to the defect-causing factor.

For example, if the facility data is OES data, the electronic device may identify the material (etching by-product) corresponding to the defect-causing factor based on the wavelength corresponding to the defect-causing factor.

For example, if the facility data is measurement data according to the position on the semiconductor wafer (e.g., the distance from the reference point), at least one factor may include factors for each of a plurality of regions divided according to the position on the semiconductor wafer. The electronic device may identify a region on the semiconductor wafer that corresponds to a defect-causing factor among a plurality of regions. In other words, the electronic device may identify a location on the semiconductor wafer where defects are predicted to occur.

The electronic device can identify the time section of the target process corresponding to the defect-causing factor and identify the depth section of the hole corresponding to the identified time section. The identified depth section may be a depth section where defects are predicted to occur.

The electronic device may identify the type of defect depending on whether the defect-causing factor is greater or less than a specified value. For example, if the facility data is OES data, the electronic device may determine that the amount of etching by-products is excessive if the defect-causing factor is greater than a specified value, and it can be predicted that defects will occur due to over-etching. If the defect-causing factor is less than a specified value, the electronic device may determine that the amount of etching by-products is insufficient, and it can be predicted that defects will occur due to insufficient etching.

The electronic device may be configured to determine the cause of the defect based on information about the material associated with the defect-causing factor, whether the defect-causing factor is greater or less than a specified value, information about a time section corresponding to the defect-causing factor, and/or information about a region on the semiconductor wafer corresponding to the defect-causing factor. For example, an electronic device may identify a cause of a defect corresponding to a defect-causing factor based on information on the cause of the defect related to each factor organized by factor. Defect cause information for each factor may be stored in the memory (e.g., memory 110 in FIG. 2) of the electronic device. The cause of the defect corresponds to the defect-causing factor may relates to the material related to the defect-causing factor, whether the defect-causing factor is greater or less than a specified value, information about a time section corresponding to the defect-causing factor, and/or information about a region on a semiconductor wafer corresponding to the defect-causing factor.

In operation 1030, the electronic device may determine process conditions for a subsequent wafer based on the extracted factors. The electronic device may determine process conditions for a subsequent wafer based on the process conditions of the step of the target process that includes the time section corresponding to the defect-causing factor. The electronic device may change the process conditions related to the cause of the defect among the process conditions of the target process that includes a time section corresponding to the defect-causing factor. For example, when the cause of the defect is high temperature, the electronic device may determine to lower the temperature among the process conditions of a step of the target process that includes a time section corresponding to the defect-causing factor.

An electronic device according to an embodiment may extract defect-causing factors that increase the defect index and determine process conditions for a subsequent wafer based on the defect-causing factors. Accordingly, electronic devices may diagnose the cause of defects and derive improvement measures immediately after the target process without completing the entire process, shorten the product development period and shorten the verification period of a new facility when expanding the facility.

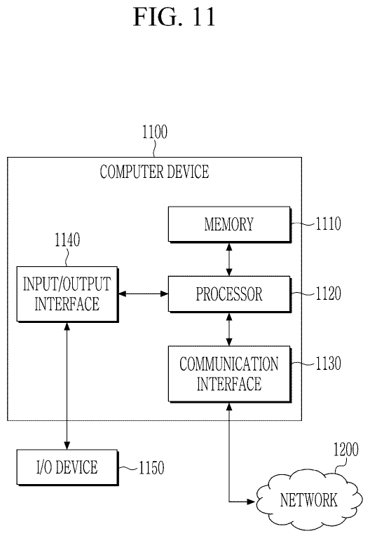

FIG. 11 is a diagram illustrating an example of a computer device 1100 implementing an electronic device according to an embodiment of the inventive concept. The electronic device 101 of FIG. 2 may be implemented by the computer device 1100 shown in FIG. 11.

Referring to FIG. 11, the computer device 1100 may include a memory 1110, at least one processor 1120, a communication interface 1130, and an input/output interface 1140.

The memory 1110 may be a computer-readable recording medium and may include a permanent mass storage device such as, for example, random access memory (RAM), read-only memory (ROM), and a disk drive. Additionally, an operating system and at least one program code may be stored in the memory 1110. These software components may be loaded into the memory 1110 from a computer-readable recording medium separate from the memory 1110. Such separate computer-readable recording media may include computer-readable recording media such as hard disks, flash memory, optical disks, and external hard disks. Additionally, these software components may be loaded into the memory 1110 through the communication interface 1130.

The processor 1120 may be configured to process instructions of a computer program by performing basic arithmetic, logic, and input/output operations. Commands may be provided to the processor 1120 by the memory 1110 or the communication interface 1130.

The communication interface 1130 may provide a function for the computer device 1100 to communicate with other devices through a network 1200. The communication method is not limited, and may include not only a communication method utilizing a communication network that the network 1200 may include (e.g., a mobile communication network, wired Internet, wireless Internet, or a broadcast network), but also short-range wireless communication between devices. For example, the network 1200 may include one or more of a personal area network (PAN), a local area network (LAN), a campus area network (CAN), a metropolitan area network (MAN), a wide area network (WAN), and a broadband network (BBN), the Internet, etc. Additionally, the network 1200 may include one or more of various network topologies, including a bus network, a star network, a ring network, a mesh network, a star-bus network, a tree network or a hierarchical network, but is not limited to these.

The input/output interface 1140 may serve as an interface that can transmit commands or data input from the user or an input/output (I/O) device 1150 to other component(s) of the computer device 1100. Additionally, the input/output interface 1140 may output commands or data received from another component(s) of the computer device 1100 to the user or the input/output device 1150. For example, the input/output device 1150 may include an input device such as a microphone, keyboard, or mouse, and the output device may include an output device such as a display or speaker.

The embodiments described above may be implemented in the form of a computer program that can be executed through various components on a computer, and such a program may be recorded on a computer-readable medium. At this time, the medium is magnetic media such as hard disks, floppy disks, and magnetic tapes, optical recording media such as CD-ROMs and DVDs, magneto-optical media such as floptical disks, and hardware devices specifically configured to store and execute program instructions, such as ROM, RAM, flash memory, etc.

Unless there is an explicit order or description to the contrary regarding the steps constituting the method according to the embodiments, the steps may be performed in an appropriate order. The present invention is not necessarily limited by the order of description of the above steps.

The use of any examples or exemplary terms in this specification is merely for illustrating the present invention in detail and is not intended to limit the scope of the present invention. Additionally, those skilled in the art will recognize that various modifications, combinations, and changes may be made within the scope of the claims or their equivalents.

Although the embodiments have been described in detail above, the scope of the present invention is not limited thereto, and various modifications and improvements made by those skilled in the art using the basic concepts of the present invention defined in the following claims are also possible.

What is claimed is:

1. An electronic device, comprising:
a communication circuit;
at least one processor; and
a memory;
wherein the memory is configured to store instructions that, when executed by the at least one processor, cause the electronic device:
to obtain real-time facility data while a target process for a semiconductor wafer is in progress, the target process being divided into a plurality of time sections;
to post-process the real-time facility data;
to generate at least one factor that quantifies a process state for each of the plurality of time sections of the target process based at least in part on the processed real-time facility data; and
to predict a defect index of the target process based at least in part on the at least one factor.

2. The electronic device of claim 1, wherein:
the real-time facility data comprises a value measured by a sensor of a facility in which the target process is performed and includes a first measurement value indicating signal intensity over time, and
the instructions, when executed by the at least one processor, further cause the electronic device to standardize the first measurement value by dividing a value that changes during the target process by a constant value during the target process, and to smooth the first measurement value.

3. The electronic device of claim 2, wherein:
the real-time facility data further includes a second measurement value indicating signal intensity as a function of wavelength, and
the instructions, when executed by the at least one processor, further cause the electronic device to normalize the second measurement value by dividing an average signal intensity in a first wavelength range by an average signal intensity in a second wavelength range that includes the first wavelength range and is wider than the first wavelength range.

4. The electronic device of claim 1, wherein:
the real-time facility data includes measurements of signal intensity over time,
the instructions, when executed by the at least one processor, further cause the electronic device to generate the at least one factor using an average signal intensity of each of the plurality of time sections and an average signal intensity of each of at least two of the plurality of time sections, and
the at least one factor includes an absolute factor that is the average signal intensity of each of the plurality of time sections and a calculation factor that is obtained by calculating the average signal intensity of each of the at least two of the plurality of time sections.

5. The electronic device of claim 4, wherein:
the calculation factor comprises
first factors that are a ratio of an average signal intensity of each of the plurality of time sections for each step of the target process to an average signal intensity of the first time section of the plurality of time sections within the same step,
second factors that are a ratio of the average signal intensity of each of the plurality of time sections to an average signal intensity of the first time section of the first step of the target process, and
third factors that are a ratio of an average signal intensity of an (n+1)th one of the plurality of time sections to an average signal intensity of an n th one of the plurality of time sections.

6. The electronic device of claim 1, wherein:
the real-time facility data includes a value measuring an intensity of a signal as a function of a location within a chamber used for the target process or on the semiconductor wafer, and
the instructions, when executed by the at least one processor, further cause the electronic device to generate at least one factor that quantifies the process state for each region divided according to a distance from a reference point of the chamber or the semiconductor wafer based at least in part on the real-time facility data.

7. The electronic device of claim 1, wherein:
the target process includes a plurality of processes;
the instructions, when executed by the at least one processor, further cause the electronic device to generate the at least one factor based at least in part on real-time facility data corresponding to the plurality of processes, and
to predict a defect index related to a defect occurring due to the plurality of processes based at least in part on the at least one factor; and
the plurality of processes include sub-processes included in a process for forming one structure, or include processes for forming each of a plurality of structures.

8. The electronic device of claim 1, wherein:
the target process includes at least one of an etching process, a deposition process, or an annealing process.

9. The electronic device of claim 1, wherein:
the target process includes a process of etching a hole having a depth, and
the at least one factor quantitatively represents a degree of etching for each depth section of the hole, and depth sections of the hole respectively correspond to the plurality of time sections of the target process.

10. The electronic device of claim 9, wherein:
the instructions, when executed by the at least one processor, further cause the electronic device to obtain a profile of the hole based at least in part on the at least one factor, and
to predict a defect index of the target process based at least in part on the profile of the hole.

11. The electronic device of claim 1, wherein:
the instructions, when executed by the at least one processor, further cause the electronic device to generate a process defect prediction model based at least in part on the at least one factor, process information of the target process, and an actual defect index for each wafer, and
to predict a defect index for subsequent wafers based at least in part on the process defect prediction model.

12. The electronic device of claim 1, wherein:
the instructions, when executed by the at least one processor, further cause the electronic device to transmit defect prediction information including the predicted defect index and information on a given one of the plurality of time sections of the target process in which defect occurrence is predicted to a yield management system through the communication circuit.

13. The electronic device of claim 1, wherein:
the instructions, when executed by the at least one processor, further cause the electronic device to determine whether to proceed with the target process based at least in part on the predicted defect index, and
to transmit a control signal to a facility control device through the communication circuit based at least in part on whether to proceed with the target process.

14. The electronic device of claim 1, wherein:
the instructions, when executed by the at least one processor, further cause the electronic device to extract a factor that affects the predicted defect index among the at least one factor, based at least in part on the predicted defect index being greater than or equal to a threshold value, and
to determine a cause of a defect and a process condition for subsequent wafers based at least in part on the extracted factor.

15. The electronic device of claim 1, wherein:
the instructions, when executed by the at least one processor, further cause the electronic device to determine a defect level of subsequent wafers based at least in part on the predicted defect index for subsequent wafers, and
to determine a process flow of the subsequent wafers based at least in part on the determined defect level.

16. An electronic device, comprising:
a communication circuit;
at least one processor; and
a memory,
wherein the memory stores instructions that, when executed by the at least one processor, cause the electronic device to obtain real-time facility data while a target process for forming at least one structure on a semiconductor wafer is in progress,
to post-process the real-time facility data,
to divide the processed real-time facility data into a plurality of time sections,
to generate at least one factor based on facility data for each of the plurality of time sections or facility data for at least two of the plurality of time sections, and
to predict a defect index of the target process based at least in part on the at least one factor.

17. The electronic device of claim 16, wherein:
the at least one factor includes average values of facility data for each of the plurality of time sections and values calculated by combining the average values of facility data for each time section.

18. The electronic device of claim 16, wherein:
the real-time facility data includes measurement values according to a location within a chamber used in the target process or a location on the semiconductor wafer,
the instructions, when executed by the at least one processor, further cause the electronic device to obtain facility data for each region of the chamber or the semiconductor wafer by dividing the real-time facility data by a distance from a reference point of the chamber or the semiconductor wafer, and
to further generate at least one factor based at least in part on facility data for each region of the chamber or the semiconductor wafer or facility data for at least two regions of the chamber or the semiconductor wafer.

19. The electronic device of claim 18, wherein:
the at least one factor includes average values of facility data in each region of the chamber or the semiconductor wafer and values calculated by combining the average values of facility data in each region of the chamber or the semiconductor wafer.

20. A method of operating an electronic device, comprising:
obtaining real-time facility data while a target process for a semiconductor wafer is in progress, the target process being divided into a plurality of time sections;
post-processing the real-time facility data;
generating at least one factor that quantifies a process state for each of the plurality of time sections of the target process based at least in part on the processed real-time facility data; and
predicting a defect index of the target process based at least in part on the at least one factor.
